(19) United States
(12) Patent Application Publication
(10) Pub. No.: US 2002/0017653 A1
(43) Pub. Date: Feb. 14, 2002

(54) Blue light emitting diode with sapphire substrate and method for making the same

(76) Inventor: Feng-Ju Chuang, Hsin Chu (TW)

Correspondence Address: Rosenberg, Klein & Bilker, 3444 Ellicott Center Drive-Suite 105, Ellicott City, MD, 21043, US

(21) Appl. No.: 09/774,036

(22) Filed: Jan. 31, 2001

Related U.S. Application Data
(62) Division of application No. 09/383,358, filed on Aug. 26, 1999, now abandoned.

(51) Int. Cl. H01L 33/00

(52) U.S. Cl. 257/103

(57) ABSTRACT

A blue light emitting diode with sapphire substrate and method for making the same is disclosed. The blue light emitting diode comprises a sapphire substrate having a at least one channel penetrating the sapphire substrate, two GaN thin film with similar thickness on top and bottom surface of the sapphire substrate and in contact with in the channel, an anode and a cathode on the bottom surface of the lower GaN thin film and the upper surface of the epitaxy layer. The arrangement of the channel provides a conductive passage between the anode and the cathode and realizes a vertical type LED with reduced operation area. Moreover, the polishing process is simplified and the yield is enhanced.

### FIELD OF THE INVENTION

The present invention relates to a blue light emitting diode with sapphire substrate and method for making the same, especially to a blue light emitting diode with sapphire substrate wherein at least one channel is formed within the sapphire substrate to provide current flowing passage and an upper and a lower GaN thin film with similar thickness is formed on top surface and lower surface of the sapphire substrate, respectively, thus providing a vertical type LED with reduced thickness and active area.

### BACKGROUND OF THE INVENTION

The LEDs have found wide applications in computer peripheral, instrument display and other consumer product due to the advantages of long endurance, compact size, low thermal energy generation, low power consumption, and high speed operation since the first development in 1960s. More particularly, the recent mature development of the high-brightness LEDs facilitates outdoor usage such as advertising display, traffic sign or VMS. On virtue of the larger-distance display requirement for outdoor application, the further enhancement of the LED brightness is crucial for the feasibility of LED in outdoor usage.

The present blue light emitting diodes are generally adopted sapphire or SiC as substrates. More particularly, the sapphire substrate is superior than the SiC substrate in the aspects of brightness, contrast, and electrical conductivity, therefore becomes a more promising substrate material.

FIG. 1 shows the cross section view of a blue light emitting diode with sapphire substrate. As shown in this figure, the blue LED with sapphire substrate at least comprises a sapphire substrate 10, a gallium nitride (GaN) thin film 12 on the sapphire substrate 10, an epitaxy layer 14 with a p-n junction for emitting blue light and formed on the GaN thin film 12 by sputtering or evaporation. Moreover, the sapphire substrate 10 in essence is an electrical insulator, a first electrode 16 (anode) and a second electrode 18 (cathode) are formed on the top of the epitaxy layer 14 in a co-planar fashion.

However, the blue LED with above-mentioned structure has following drawbacks:

1. On virtue of the electrical insulation property of the sapphire substrate 10, the anode 16 and the cathode 18 are formed on the top of the epitaxy layer 14 in a co-planar fashion. Therefore, the area occupied by electrode is increased and the blue LED is hard to scale down.

2. On virtue of the electrical insulation property of the sapphire substrate 10, the problem of static electricity is more liable to occur and the yield is reduced.

3. The sapphire substrate 10 has the problem of crack due to uneven strain induced by the GaN thin film 12 with thickness H₁₁ (3-4 μm) during annealing process. The thickness H₁ of the sapphire substrate 10 should be larger than 280 μm and in general larger than 300 μm during mass production. The thickness ratio of H₁ and H₁₁ is as high as 100:1, and the die cutting process is difficult due to the large thickness ratio.

4. To facilitate the diamond scribing process by a diamond-tipped tool or a pulsed laser beam in later stage, the sapphire substrate 10 is removed about 200 μm thickness by high hardness material such as diamond. This process is cumbersome.

### OBJECTS AND SUMMARY OF THE INVENTION

It is an object of the present invention to provide a blue light emitting diode with sapphire substrate wherein at least one channel is formed on the sapphire substrate to provide current flowing passage between upper and lower electrodes, thus providing a vertical type LED with reduced operation area.

It is another object of the present invention to provide a blue light emitting diode with sapphire substrate wherein an upper and a lower GaN thin film with similar thickness is formed on top surface and lower surface of the sapphire substrate, respectively such that the stress of the upper and the lower GaN thin film can counteract each other during annealing. In this way, the thickness of the sapphire substrate can be reduced to as small as 150 μm, or even below 100 μm, thus saving substrate material and following polishing task while the problem of cracking is prevented.

It is still another object of the present invention to provide a blue light emitting diode with sapphire substrate wherein at least one channel is formed on the sapphire substrate to provide current flowing passage to prevent the problem of static electricity and enhance yield of LED.

The various objects and advantages of the present invention will be more readily understood from the following detailed description when read in conjunction with the appended drawing, in which:

### BRIEF DESCRIPTION OF THE DRAWINGS:

FIG. 1 shows the cross section view of a blue light emitting diode with sapphire substrate;

FIG. 2 shows the cross section view of LED structure according to a preferred embodiment of the present invention;

FIGS. 3A to 3E shows the cross section of the processing steps for fabricating the LED according to the present invention; and

FIG. 4 shows the cross section view of LED according to another embodiment of the present invention.

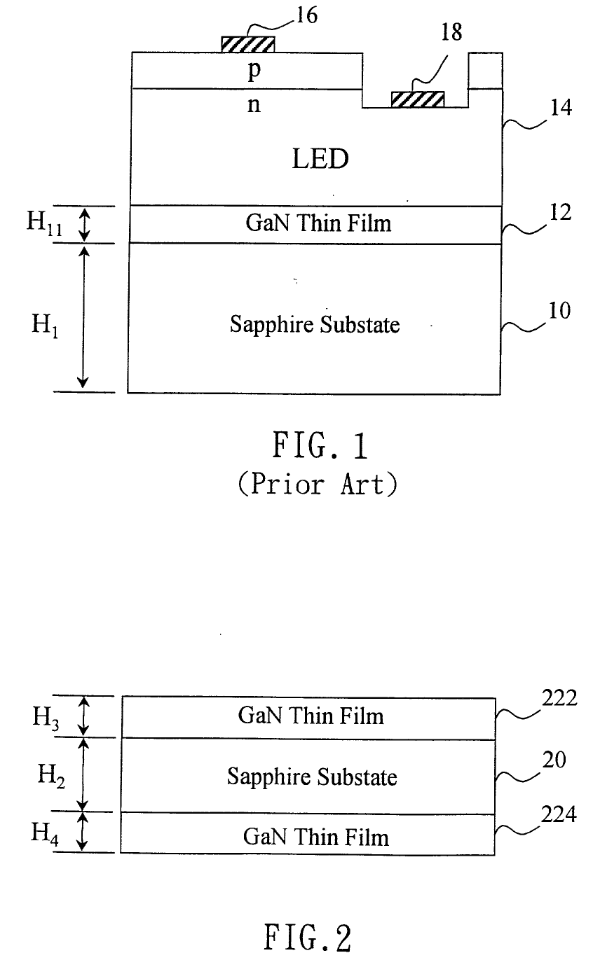

### DETAILED DESCRIPTION OF PREFERRED EMBODIMENTS

FIG. 2 shows the cross section view of LED structure according to a preferred embodiment of the present invention. As stated before, the GaN thin film formed on the sapphire substrate will induce considerable stress on the sapphire substrate during annealing process. Therefore, the thickness of the sapphire substrate should be increased to such extent to resist the induced stress and be free from cracking. In the present invention, an upper GaN thin film 222 (thickness H3) and a lower GaN thin film 224 (thickness H3) with similar thickness are formed on the top surface and bottom surface of the sapphire substrate 20, respectively. The stress induced by the upper GaN thin film 222 and the lower GaN thin film 224 on the sapphire substrate 20 will counteract each other during annealing process. The sapphire substrate 20 will not be subjected to a net high stress and prevented from cracking. Therefore, the thickness requirement on the sapphire substrate 20 is alleviated. According to experimental result, the thickness of the sapphire substrate can be reduced to as small as 150 μm, or even below 100 μm, thus saving substrate material and following polishing task while the problem of cracking is prevented.

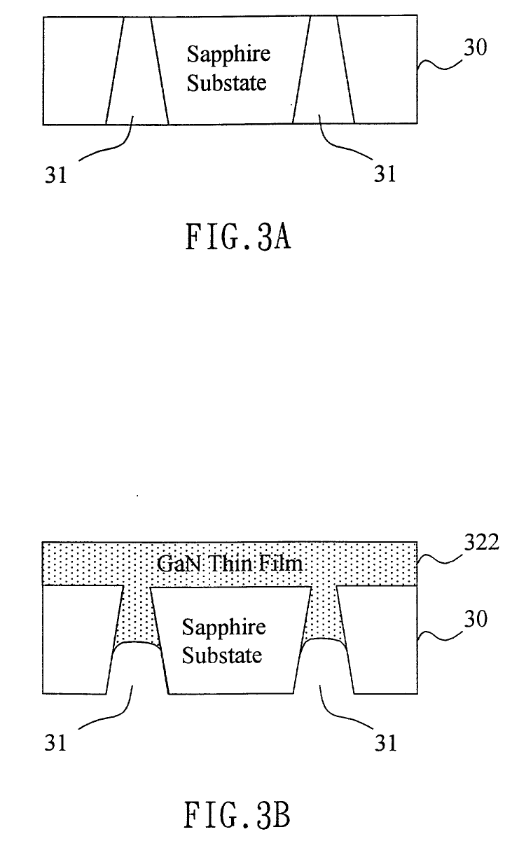

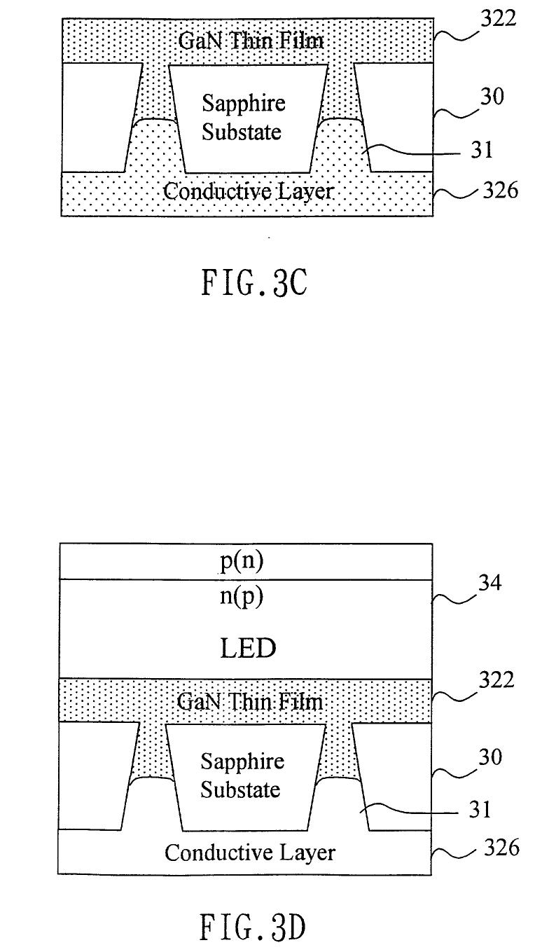

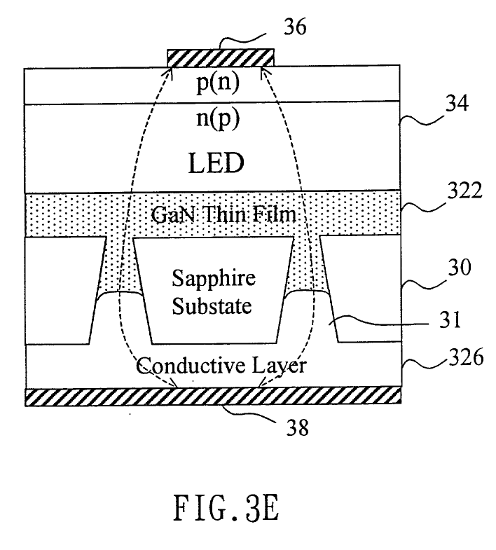

FIGS. 3A to 3E shows the cross section of the processing steps for fabricating the LED according to the present invention, wherein those processing steps include:

Step 1: as shown in FIG. 3A, preparing a sapphire substrate 30 with thickness smaller than 100 μm and forming a tapered channel 31 penetrating the sapphire substrate 30 by chemical etching or photo lithograph;

Step 2: as shown in FIG. 3B, forming a GaN thin film 322 on top surface of the sapphire substrate 30 by epitaxy growth process such as MOVPE, and part of the GaN thin film 322 presents in the tapered channel 31;

Step 3: as shown in FIG. 3C, forming a conductive layer 326 on the bottom surface of the sapphire substrate 30 by epitaxy growth or sputtering, the conductive layer 326 being made of non-metallic material and presenting in the remaining space of the tapered channel 31 not occupied by the GaN thin film 322 such that the GaN thin film 322 is in contact with the conductive layer 326 to provide electrical connection;

Step 4: as shown in FIG. 3D, forming an LED epitaxy layer 34 with a p-n junction (or n-p junction as shown in the parenthesis) for emitting blue light on the top surface of the Ga thin film 322 by sputtering or evaporation; and

Step 5: as shown in FIG. 3E, forming an upper electrode 36 on the top surface of the LED epitaxy layer 34 and a lower mating electrode 38 on the bottom surface of the conductive layer 326, respectively.

The LED epitaxy layer 34, the GaN thin film 322, and the conductive layer 326 are all electrically conductive material such that an electrically conductive path is presented between the electrodes 36 and 38 through the tapered channel 31, as indicated by the dashed line in FIG. 3E. Because the upper electrode 36 and the lower electrode 38 in the present invention are not on the same plane, i.e., not coplanar, the occupied area of electrode on the front surface of the LED is reduced.

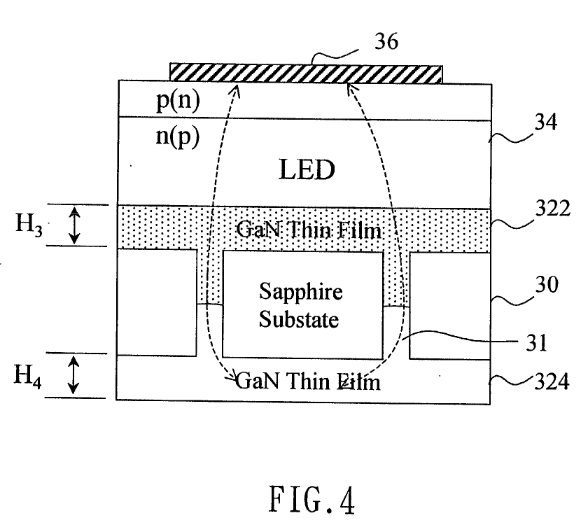

FIG. 4 shows the cross section view of LED according to another embodiment of the present invention. In this embodiment, the conductive layer 326 shown in FIGS. 3C-3E is replaced by a lower GaN thin film 324 with thickness H₄ similar to or the same as the thickness H₃ of the GaN thin film 322. Therefore, the stresses induced by the GaN thin film 322 and the lower GaN thin film 324 counteract each other during annealing process, thus preventing the cracking problem of the sapphire substrate 30 and alleviating the thickness requirement of the sapphire substrate 30.

Moreover, the channel 31 formed in above-mentioned step 1 has a tapered cross section to facilitate the formation of GaN thin film 322 and conductive layer 326 in step 3 and step 3. However, the channel 31 can also have straight cross section for simplifying the fabrication process. There is still a path for electrical current within the channel 31 as indicated by the dashed line. Moreover, the upper electrode 36 formed on the LED epitaxy layer 34 can adopt transparent electrode to enhance the brightness of the LED. Further, the lower electrode 38 can be eliminated from the LED structure because the lower GaN thin film 324 and the conductive layer 326 are also electrically conductive and can be used to replace the function of the lower electrode 38.

Although the present invention has been described with reference to the preferred embodiment thereof, it will be understood that the invention is not limited to the details thereof. Various substitutions and modifications have suggested in the foregoing description, and other will occur to those of ordinary skill in the art. For examples, an impurity layer such as AlGaInP layer can be incorporated between the epitaxy layer and the GaN thin film, or additional layer such as SiC, AlN, SiO₂, InGaN, SnO₂, AlGaInP can be provided on other thin film layer. Therefore, all such substitutions and modifications are intended to be embraced within the scope of the invention as defined in the appended claims.

1. A blue light emitting diode with sapphire substrate comprising:
an epitaxy layer with a p-n junction for emitting blue light;
a GaN thin film formed on the bottom surface of said epitaxy layer;
a sapphire substrate formed on the bottom surface of said GaN thin film and having at least one channel penetrating said sapphire substrate such that part of said GaN thin film presents in said channel;
a first electrode formed on top surface of said epitaxy layer, and
a conductive layer composed of conductive material and formed on the bottom surface of said sapphire substrate and part of said conductive material presents in said channel and is contact with said GaN thin film within said channel, said conductive layer being the mating electrode of said first electrode.

2. The blue light emitting diode with sapphire substrate as in claim 1, wherein said conductive layer is made of non-metal conductive material.

3. The blue light emitting diode with sapphire substrate as in claim 1, wherein the thickness of said GaN thin film and conductive layer are similar.

4. The blue light emitting diode with sapphire substrate as in claim 1, wherein said conductive layer is a lower GaN thin film.

5. The blue light emitting diode with sapphire substrate as in claim 4, wherein said GaN thin film and said lower GaN thin film have same thickness.

6. The blue light emitting diode with sapphire substrate as in claim 1, wherein said channel is a tapered channel with oblique sidewall.

7. The blue light emitting diode with sapphire substrate as in claim 1, wherein said channel has straight sidewall.

8. The blue light emitting diode with sapphire substrate as in claim 1, wherein the thickness of said sapphire substrate is larger than 0 μm and not larger than 150 μm.

9. The blue light emitting diode with sapphire substrate as in claim 1, wherein said first electrode is a transparent electrode.

10. The blue light emitting diode with sapphire substrate as in claim 1, further comprises a second electrode on the bottom surface of said conductive layer.

11. A method for manufacturing a blue light emitting diode with sapphire substrate, comprising the steps of:
(1) preparing a sapphire substrate and forming at least one channel penetrating said sapphire substrate;
(2) forming a GaN thin film on the top surface of said sapphire substrate, and part of said GaN thin film presenting in said channel;
(3) forming a conductive layer on the bottom surface of said sapphire substrate, said conductive layer made of conductive material and part of said conductive material presenting in the remaining space of said channel not occupied by said GaN thin film such that said GaN thin film is in contact with said conductive layer;
(4) forming an LED epitaxy layer with a p-n junction on the top surface of said GaN thin film; and
(5) forming a first electrode on the top surface of said LED epitaxy layer.

12. The method as in claim 11, wherein said channel in said step (1) is a tapered channel.

13. The method as in claim 11, wherein said GaN thin film in said step (2) is formed on top surface of said sapphire substrate by metal organic vapor phase epitaxy (MOVPE).

14. The method as in claim 11, wherein said conductive layer in said step (3) made of non-metal conductive material.

15. The method as in claim 11, wherein said GaN thin film formed in said step (2) and said conductive layer formed in said step (3) have similar thickness.

16. The method as in claim 11, wherein said conductive layer formed in said step (3) is made of GaN.

17. The method as in claim 16, wherein said GaN thin films formed in said step (2) and (3) have same thickness.

18. The method as in claim 11, wherein the thickness of said sapphire substrate formed in said step (1) is larger than 0 μm and not larger than 150 μm.

19. The method as in claim 11, wherein said first electrode formed in said step (5) is a transparent electrode.

20. The method as in claim 11, further comprising a sixth step for forming a second electrode on the bottom surface of said conductive layer and being the mating electrode to said first electrode.
